(19) United States
(12) Patent Application Publication
(10) Pub. No.: US 2026/0050007 A1
(43) Pub. Date: Feb. 19, 2026

(54) ELECTRONIC ELEMENT TESTING DEVICE WITH FASTENING-BASED DEPRESSING MECHANISM AND METHOD THEREOF

(71) Applicant: CHROMA ATE INC., Taoyuan City (TW)

(72) Inventors: Tsung-Wei Ke, Taoyuan City (TW); Chien-Ming Chen, Taoyuan City (TW); Chin-Yi Ou Yang, Taoyuan City (TW); I-Ching Tsai, Taoyuan City (TW); Xin-Yi Wu, Taoyuan City (TW); Yun-Jui Cheng, Taoyuan City (TW)

(73) Assignee: CHROMA ATE INC., Taoyuan City (TW)

(21) Appl. No.: 19/191,617

(22) Filed: Apr. 28, 2025

(30) Foreign Application Priority Data
Aug. 16, 2024 (TW) 113131006

(51) Int. Cl. G01R 1/04

(52) U.S. Cl. CPC G01R 1/0466

(57) ABSTRACT

An electronic element testing device with a fastening-based depressing mechanism includes a carrier platform, a support frame, a depressing mechanism, a displacement adjustment module, and a test socket. The support frame is arranged on the carrier platform. The depressing mechanism is connected to the support frame. The depressing mechanism includes a lifting module, a depressing head, and a fastening module. The depressing head is connected to the lifting module. The lifting module is configured to drive the depressing head to move toward or away from the carrier platform. The fastening module is configured to fasten the lifting module. The displacement adjustment module is arranged above the carrier platform. The test socket includes a slot for accommodating an electronic element. The test socket is connected to the displacement adjustment module. The displacement adjustment module is configured to adjust displacement of the test socket in at least one axial direction.

### CROSS-REFERENCE TO RELATED APPLICATION

This non-provisional application claims priority under 35 U.S.C. § 119(a) to patent application No. 113131006 filed in Taiwan, R.O.C. on Aug. 16, 2024, the entire contents of which are hereby incorporated by reference.

### BACKGROUND

### Technical Field

The present invention relates to an electronic element testing device and a method thereof, and in particular, to a pressure measurement-based testing device and a method thereof.

### Related Art

In modern society, as technology continues to evolve, functionality and computing power of chips have become increasingly powerful. In addition, a larger quantity of contacts or pins need to be arranged on the chip in design, to accommodate powerful performance of the chips. When a chip is tested, to ensure correct inspection, a sufficient depressing force need to be applied to ensure that the chip and spring probes are in full contact, thereby ensuring that all contacts or pins on the chip can contact the corresponding spring probes. However, a strong depressing force often causes machine instability and material fatigue. Moreover, if a depressing head fails to be precisely attached to the chip during testing of the chip, not only testing inaccuracy may be caused, but also the chip or the spring probe may be easily damaged.

### SUMMARY

In view of this, according to some embodiments, an electronic element testing device with a fastening-based depressing mechanism is proposed, including a carrier platform, a support frame, a depressing mechanism, a displacement adjustment module, and a test socket. The support frame is arranged on the carrier platform. The depressing mechanism is connected to the support frame. The depressing mechanism includes a lifting module, a depressing head, and a fastening module. The depressing head is connected to the lifting module. The lifting module is configured to drive the depressing head to move toward or away from the carrier platform. The fastening module is configured to fasten the lifting module. The displacement adjustment module is arranged on the carrier platform. The test socket includes a slot for accommodating an electronic element. The test socket is arranged above the displacement adjustment module. The displacement adjustment module is configured to adjust displacement of the test socket in at least one axial direction.

According to some embodiments, a method for testing an electronic element by using a fastening-based depressing mechanism is further proposed, including the following steps: providing a control module to control a fastening module to release a lifting module, and controlling, by the control module, the lifting module to drive a depressing head to contact an electronic element in a test socket. The control module controls the fastening module to fasten the lifting module. An electronic element in the test socket is attached to the depressing head through the displacement adjustment module. The control module controls a depressing force generation apparatus to apply a depressing force to the electronic element. The control module tests the electronic element.

Detailed features and advantages of the present invention are described in detail in the following implementations, and the content is sufficient for any person skilled in the related art to understand the technical content of the present invention and implement the invention accordingly. According to the content, the patent application scope, and the figures disclosed in this specification, any person skilled in the related art can easily understand related objectives and advantages of the present invention.

### BRIEF DESCRIPTION OF THE DRAWINGS

FIG. 1 is a three-dimensional view of an electronic element testing device according to some embodiments.

FIG. 2 is a schematic diagram of an electronic element testing device according to some embodiments.

FIG. 3 is a block diagram of a depressing mechanism and a control module according to some embodiments.

FIG. 4 is a cross-sectional view of an adjustment member according to some embodiments.

FIG. 5 is a cross-sectional view of a fastening module of FIG. 1 at position A-A according to some embodiments.

FIG. 6 is a three-dimensional view of another embodiment of an electronic element testing device according to some embodiments.

FIG. 7 is a three-dimensional view of still another embodiment of an electronic element testing device according to some embodiments.

FIG. 8 is a block flowchart of a method for testing an electronic element according to some embodiments.

### DETAILED DESCRIPTION

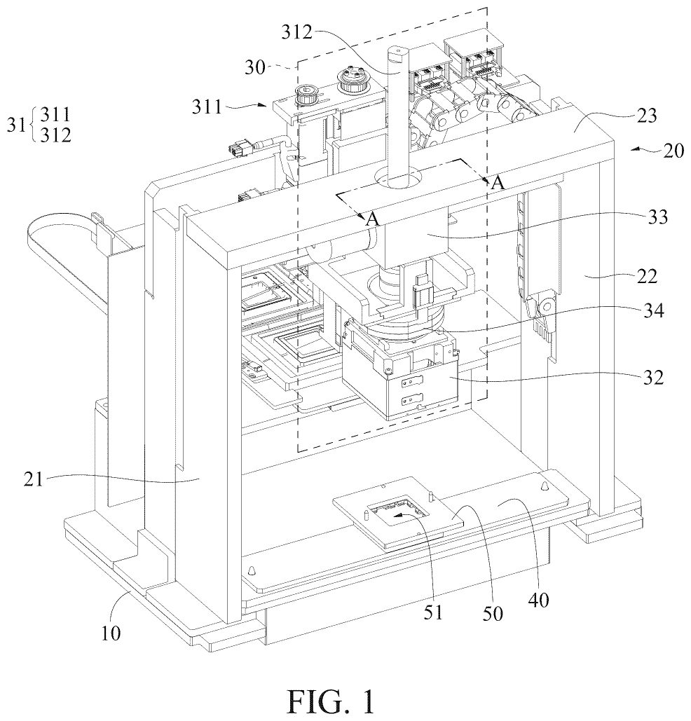

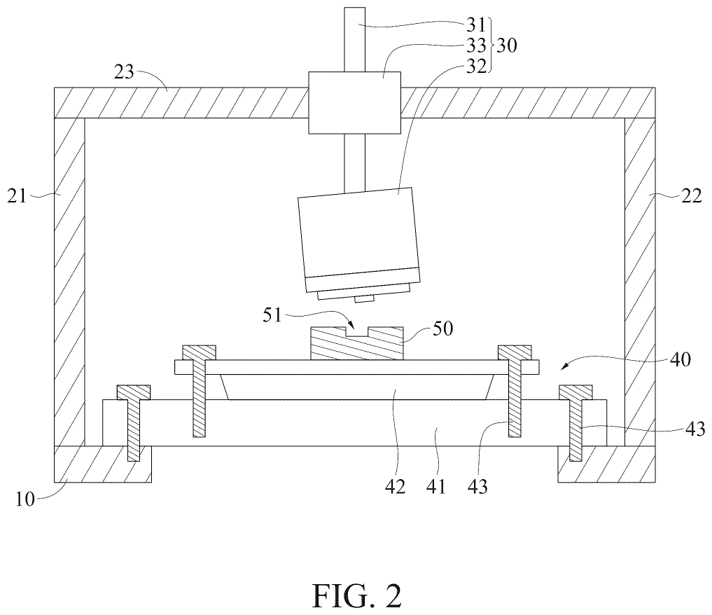

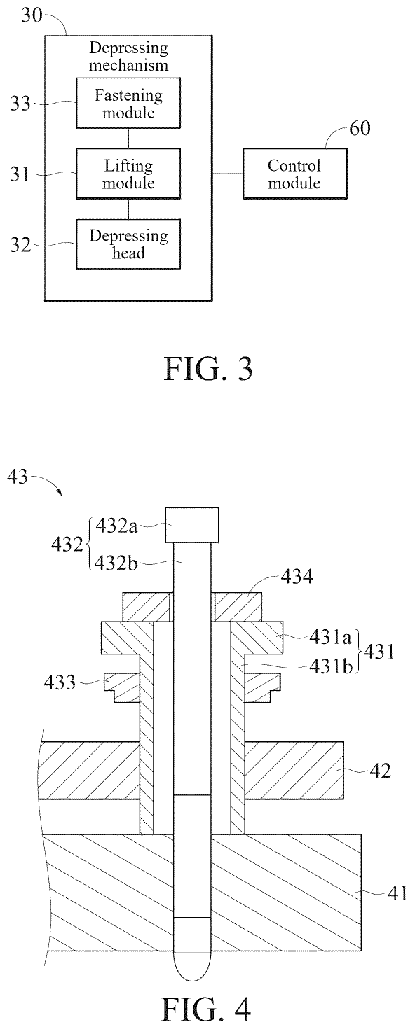

Refer to FIG. 1, FIG. 2, and FIG. 3. FIG. 1 is a three-dimensional view of an electronic element testing device according to some embodiments. FIG. 2 is a schematic diagram of an electronic element testing device according to some embodiments. FIG. 3 is a block diagram of a depressing mechanism and a control module according to some embodiments. The electronic element testing device includes a carrier platform 10, a support frame 20, a depressing mechanism 30, a displacement adjustment module 40, and a test socket 50.

The carrier platform 10 is preferably a platform or a flat plate capable of bearing weight. Based on this, the support frame 20 may be arranged on the carrier platform 10. In some embodiments, the support frame 20 includes a first support 21, a second support 22, and a top support 23. As shown in FIG. 1, the first support 21, the second support 22, and the top support 23 are in the shape of rectangular plates, and are preferably made of metal.

Herein, one end of the first support 21 is connected to one side of the carrier platform 10, and one end of the second support 22 is connected to an other side of the carrier platform 10 to correspond to the first support 21. Two ends of the top support 23 are respectively connected to an other end of the first support 21 and an other end of the second support 22, and are located between the first support 21 and the second support 22. Furthermore, the top support 23 is located between the first support 21 and the second support 22, so that the first support 21, the second support 22, and the top support 23 substantially form a U-shaped structure as a whole. Herein, the depressing mechanism 30 (to be described in detail later) is arranged on the top support 23 and located between the first support 21 and the second support 22.

The depressing mechanism 30 is connected to the support frame 20. In some embodiments, the depressing mechanism 30 includes a lifting module 31, a depressing head 32, and a fastening module 33. The lifting module 31 includes a driver 311 and a lifting shaft rod 312. In some embodiments, the driver 311 may be a lifting slider assembly composed of a motor coupled with a screw rod and a slider. In another embodiment, the driver may also be a lifting slider assembly composed of a motor coupled with a pinion and a rack. The driver 311 may also be a hydraulic cylinder, a pneumatic cylinder, or an electric cylinder. Based on this, the depressing head 32 is connected to an end of the lifting shaft rod 312, and the lifting module 31 can drive the depressing head 32 to move toward or away from the carrier platform 10.

The fastening module 33 is configured to fasten the lifting shaft rod 312. In an embodiment, the fastening module 33 is arranged on the top support 23, and is located below the center of the top support 23. The fastening module 33 further includes a through hole 33b and an air inlet 33a. The lifting shaft rod 312 passes through the through hole 33b, and the air inlet 33a is configured to be brought into communication with an air pressure source. Further, the lifting shaft rod 312 may move back and forth on the fastening module 33 through the through hole 33b of the fastening module 33. The air inlet 33a is configured to control fastening or releasing of the lifting module 31.

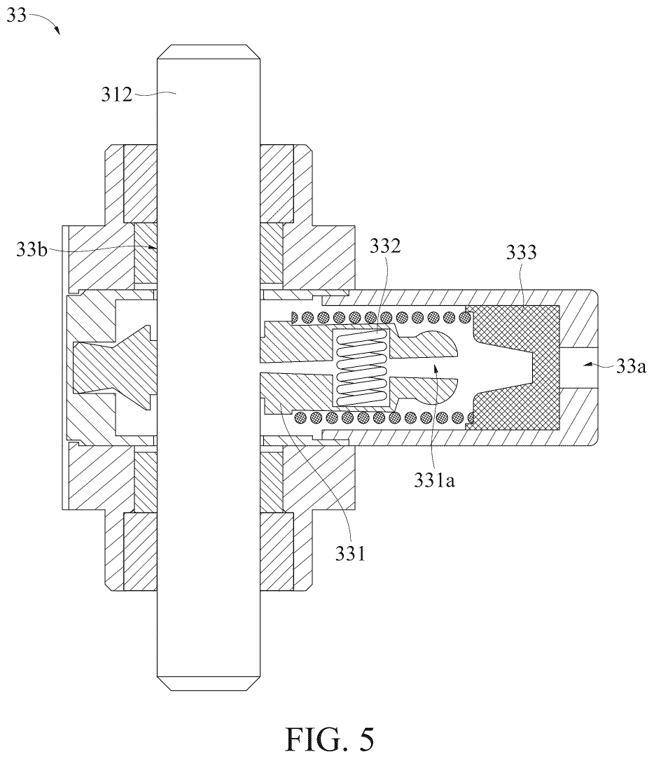

Refer to FIG. 5. FIG. 5 is a cross-sectional view of a fastening module of FIG. 1 at position A-A according to some embodiments. In some embodiments, a fastening module 33 may be a pneumatic clamping mechanism, which may be provided with a clamping block 331 and a spring 332 therein. The spring 332 is configured to drive the clamping block 331 to clamp a lifting shaft rod 312, so that the lifting shaft rod 312 may be constantly fastened.

It is to be further noted that as shown in the figure, the clamping block 331 is a V-shaped clamping block, which includes an open end 331a. The spring 332 constantly opens the open end 331a of the clamping block 331, thereby enabling an other end of the clamping block 331 to fasten the lifting shaft rod 312. On the other hand, when a high-pressure gas is supplied to the air inlet 33a, a piston block 333 is to be driven by a gas pressure to push the open end 331a of the clamping block 331, to gradually move arms of the clamping block toward each other at the open end 331a against a tension of the spring 332 to fully close one end of the clamping block 331. In this case, the other end of the clamping block 331 releases the lifting shaft rod 312, thereby releasing the lifting shaft rod 312, and the lifting module 31 may drive the depressing head 32 to move toward or away from the carrier platform 10.

However, in another embodiment, the fastening module 33 is not limited to a pneumatic clamping mechanism, or may be an electromagnetic clamping mechanism, a mechanical clamping mechanism, a hydraulic clamp, an electric clamp, a pneumatic clamp, or another equivalent apparatus or mechanism that may fasten a shaft rod.

As shown in FIG. 1 and FIG. 2 again, the displacement adjustment module 40 is arranged above the carrier platform 10. In some embodiments, the displacement adjustment module 40 can move in three axial directions. The test socket 50 includes a slot 51 for accommodating an electronic element. In some embodiments, the test socket 50 is connected to the displacement adjustment module 40. In another embodiment, the test socket 50 is connected above the displacement adjustment module 40. Based on this, the displacement adjustment module 40 can be configured to adjust displacement of the test socket 50 in at least one axial direction.

In some embodiments, the slot 51 of the test socket 50 includes an electrical interface. Herein, when the electronic element is accommodated in the slot 51, electrical connection can be performed on the electrical interface to perform testing. In an embodiment, the electrical interface includes a probe (not shown), which is configured to electrically contact a contact on a bottom surface of the electronic element.

In some embodiments, the electronic element testing device further includes a control module 60 (as shown in FIG. 3), which is electrically connected to the depressing mechanism 30. The control module 60 is configured to control the fastening module 33 of the depressing mechanism 30 to release the lifting shaft rod 312, and control the driver 311 to drive the depressing head 32 to contact the electronic element in the test socket 50. In addition, the displacement adjustment module 40 selectively adjusts displacement of the test socket 50 in at least one axial direction. In some embodiments, the displacement adjustment module 40 may electrically adjust the displacement of the test socket 50 in at least one axial direction through a servo motor or the like.

In another embodiment, the control module 60 may also implement various operating functions through a hardware circuit. An example includes, but is not limited to, a workstation, a laptop computer, a client terminal, a server, a distributed computing system, a handheld apparatus, or any other computing system or apparatus. In the most basic configuration, the control module 60 may include at least one processor and a system memory.

Further, when the electronic element testing device is to test the electronic element, especially during first installation of the device or replacement of a to-be-tested object, or after device maintenance, it is possible that a position (orientation) of the depressing head 32 cannot completely correspond to the test socket 50 due to errors or tolerances in assembly and disassembly of parts. Based on this, if the depressing head 32 is forcibly driven to contact the electronic element in the test socket 50, the electronic element or the depressing head 32 may be damaged. Even if the testing of the electronic element is completed without damaging the electronic element or the depressing head 32, the electronic element may be at a high temperature because the position (orientation) of the depressing head 32 does not completely correspond to the test socket 50, or the depressing head 32 cannot be completely attached to the electronic element. This may cause distortion of a testing result at the least, or even burn the electronic element in severe cases. As shown in FIG. 2, the position (orientation) of the depressing head 32 does not completely correspond to the position (orientation) of the test socket 50, and the depressing head 32 is slightly skewed.

Based on this, the displacement adjustment module 40 selectively adjusts the displacement of the test socket 50 in at least one axial direction. In some embodiments, the displacement adjustment module 40 may also provide adjustments in six axial directions (X, Y, Z, U, V, and W). A position of the test socket 50 may be enabled to completely correspond to a position of the depressing head 32, and a lower surface of the depressing head 32 may also be completely attached to an upper surface of the electronic element. Herein, the test socket 50 can be adjusted through only the displacement adjustment module 40 without the need to adjust the depressing mechanism 30. Moreover, this adjustment is usually required only during the first mounting. For the same to-be-tested electronic element subsequently, readjustment and calibration are not required.

In some embodiments, the displacement adjustment module 40 includes a first substrate 41 and a second substrate 42. The first substrate 41 is arranged on the carrier platform 10, and the second substrate 42 is arranged on the first substrate 41. The first substrate 41 is configured to adjust the position of the test socket 50 along an X-axis direction and a Y-axis direction. The second substrate 42 is configured to adjust the position of the test socket 50 along a Z-axis direction.

In some embodiments, the first substrate 41 and the second substrate 42 are, for example but not limited to, square metal carrier plates. The first substrate 41 is arranged above the carrier platform 10, and the second substrate 42 is arranged above the first substrate 41. In an embodiment, an area of the second substrate 42 is less than an area of the first substrate 41. When the second substrate 42 is arranged above the first substrate 41, it may be clearly seen from above that an outer edge of the first substrate 41 obviously exceeds an outer edge of the first substrate 41.

In some embodiments, the displacement adjustment module 40 further includes a plurality of adjustment members 43. The plurality of adjustment members 43 respectively pass through the first substrate 41 and the second substrate 42, so that the first substrate 41 is arranged on the carrier platform 10 and the second substrate 42 is arranged on the first substrate 41. Further, the adjustment member 43 can pass through the first substrate 41, and then the first substrate 41 is arranged on the carrier platform 10 by locking. Herein, in the same manner for the second substrate 42, the second substrate 42 is arranged on the first substrate 41 through the adjustment member 43 passing through the second substrate 42. In an embodiment, since the area of the second substrate 42 is less than the area of the first substrate 41, when the adjustment member 43 passes through the second substrate 42 and the second substrate 42 is located above the first substrate 41, the second substrate 42 does not affect the adjustment member 43 passing through the first substrate 41.

Refer to FIG. 4. FIG. 4 is a cross-sectional view of an adjustment member according to some embodiments. In some embodiments, an adjustment member 43 includes an adjustment bolt 431, a fixing bolt 432, an adjustment nut 433, and a gasket 434. The adjustment bolt 431 includes an adjustment portion 431a and a body portion 431b. In some embodiments, the adjustment portion 431a is connected to the body portion 431b, and the adjustment portion 431a and the main body portion 431b are integrally formed and include a through channel therein. In addition, an outer diameter of the adjustment portion 431a is greater than that of the body portion 431b. When viewed from the front, an appearance of the adjustment bolt 431 is substantially a T-shaped structure.

The fixing bolt 432 includes a head portion 432a and a pass-through portion 432b. In some embodiments, the head portion 432a is connected to the pass-through portion 432b, and the head portion 432a and the pass-through portion 432b are integrally formed. In addition, the head portion 432a and the pass-through portion 432b are preferably solid. Furthermore, the pass-through portion 432b is in the shape of a long column, and the head portion 432a is in the shape of a short column. A length of the pass-through portion 432b is greater than a length of the head portion 432a, and an outer diameter of the head portion 432a is greater than an outer diameter of the pass-through portion 432b. Furthermore, the outer diameter of the pass-through portion 432b is slightly less than a through channel of the adjustment bolt 431. In an embodiment, the length of the pass-through portion 432b is greater than that of the adjustment bolt 431, and the fixing bolt 432 can pass through the adjustment bolt 431 through the adjustment portion 431a to be bonded to the first substrate 41 or the second substrate 42.

In some embodiments, the adjustment nut 433 is sleeved on the body portion 431b, and an inner diameter of the adjustment nut 433 is slightly greater than an outer diameter of the body portion 431b. In still another embodiment, the gasket 434 is sleeved on the pass-through portion 432b and located between the adjustment portion 431a and the head portion 432a, to increase friction between the adjustment portion 431a and the head portion 432a.

In an embodiment, the adjustment member 43 passes through the first substrate 41 and the second substrate 42, so that the first substrate 41 is arranged on the carrier platform 10 and the second substrate 42 is arranged on the first substrate 41. An example in which the adjustment member 43 passes through the second substrate 42 to enable the second substrate 42 to be arranged on the first substrate 41 is used. When displacement of the second substrate 42 in a Z-axis direction needs to be adjusted, the fixing bolt 432 may be unscrewed first, and then the adjustment bolt 431 can be rotated through a hand, a wrench, or another tool to adjust the displacement of the second substrate 42 in the Z-axis direction. After a position of the second substrate 42 in the Z-axis direction is determined, the fixing bolt 432 is locked again, and then the adjustment nut 433 is fastened to prevent the second substrate 42 from rotating and fix the position of the second substrate 42.

Refer to FIG. 1 again. In some embodiments, the depressing mechanism 30 further includes a depressing force generation apparatus 34 which is configured to apply a depressing force to the electronic element in the test socket 50. Herein, the depressing force generation apparatus 34 is preferably arranged between a depressing head 32 and the fastening module 33. During testing of the electronic element, the depressing force generated by the depressing force generation apparatus 34 enables a contact below the electronic element to more completely contact a probe in the test socket 50.

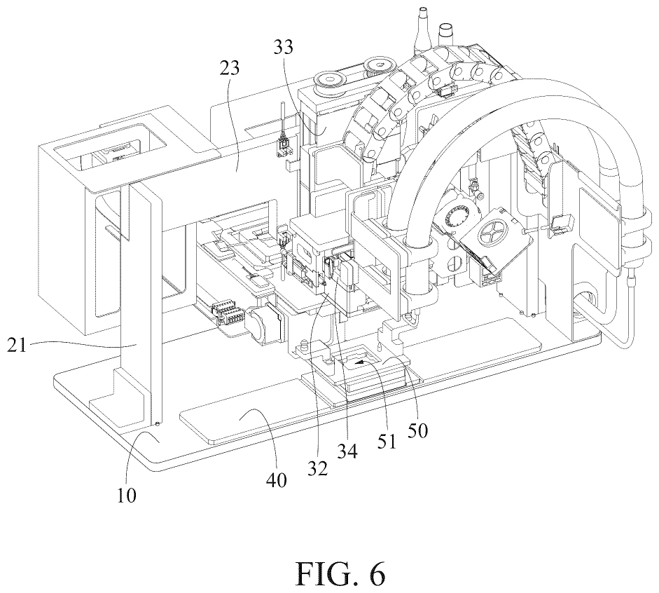

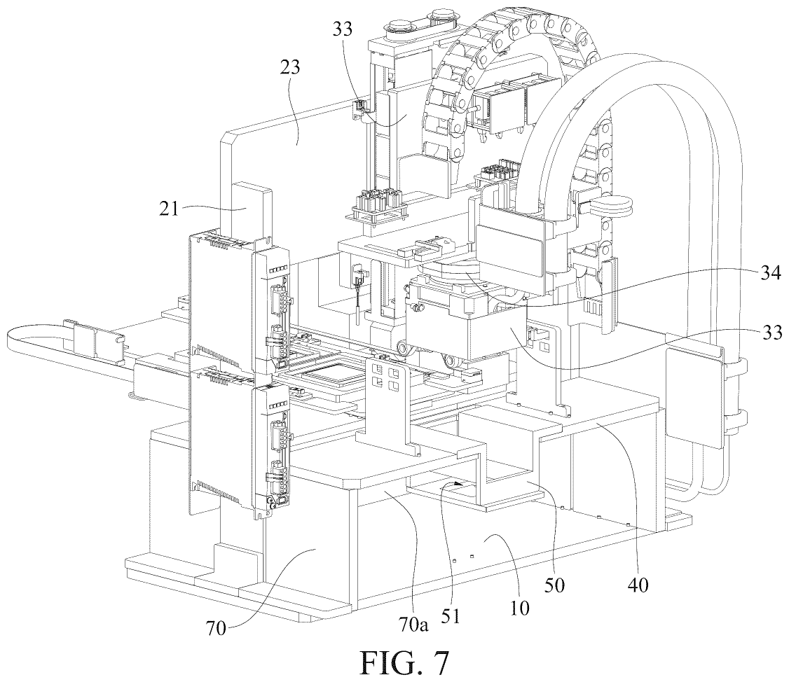

Refer to FIG. 6 and FIG. 7. FIG. 6 is a three-dimensional view of another embodiment of an electronic element testing device according to some embodiments. FIG. 7 is a three-dimensional view of still another embodiment of an electronic element testing device according to some embodiments. Herein, the two embodiments of FIG. 6 and FIG. 7 are slightly different from the embodiment of FIG. 1 in appearance and structure. As shown in FIG. 6 and FIG. 7, a top support 23 is arranged vertically. Further, in the embodiment of FIG. 1, the top support 23 is parallel to the carrier platform 10. In the two embodiments of FIG. 6 and FIG. 7, the top support 23 is perpendicular to the carrier platform 10. Based on this, the depressing mechanism 30 is arranged on a side surface of the top support 23. Further, as seen from FIG. 1, most of the depressing mechanism 30 is located below the top support 23, and as seen from FIG. 6 and FIG. 7, the depressing mechanism 30 is located beside the top support 23.

In addition, the embodiment of FIG. 7 is different from the foregoing embodiments of FIG. 1 and FIG. 6 in that the embodiment of FIG. 7 further includes a plate rack 70, which is arranged below the displacement adjustment module 40 and on the carrier platform 10, and is separated from the displacement adjustment module 40 and the carrier platform 10 by a space 70a. Based on this, when the test socket 50 is arranged above the displacement adjustment module 40, a portion of a structure thereof may be extended and placed in the space 70a.

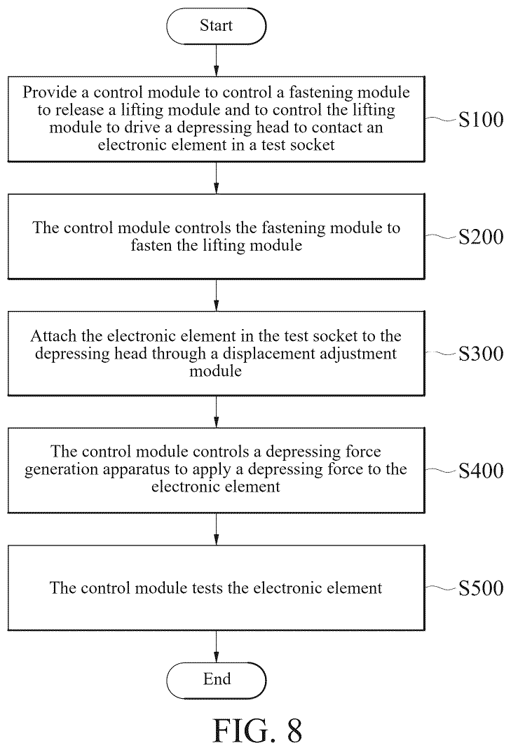

The present invention further provides a method for testing an electronic element by using a fastening-based depressing mechanism. Refer to FIG. 3 and FIG. 8 together. FIG. 8 is a block flowchart of a method for testing an electronic element according to some embodiments. In some embodiments, the method for testing an electronic element includes the following steps.

Step S100: Provide a control module 60, where the control module 60 controls a fastening module 33 to release a lifting module 31, and the control module 60 controls the lifting module 31 to drive a depressing head 32 to contact an electronic element in a test socket 50.

Step S200: The control module 60 controls the fastening module 33 to fasten the lifting module 31. Before this step, when the control module 60 controls the lifting module 31 to drive the depressing head 32 to contact the electronic element in the test socket 50, it means that the depressing head 32 has reached a positioning point. In this case, the control module 60 controls the fastening module 33 to fasten the lifting module 31, so that the lifting module 31 cannot move.

Step S300: Enable the electronic element in the test socket 50 to be attached to the depressing head 32 through a displacement adjustment module 40 (refer to FIG. 1 together). In this step, after the control module 60 controls the lifting module 31 to drive the depressing head 32 to contact the electronic element in the test socket 50, a position of the depressing head 32 may not completely correspond to the test socket 50. Therefore, the displacement adjustment module 40 may be configured to adjust displacement of the test socket 50 in at least one axial direction, so that the position of the test socket 50 can completely correspond to the position of the depressing head 32, and the electronic element in the test socket 50 can be attached to the depressing head 32.

Step S400: The control module 60 controls a depressing force generation apparatus 34 to apply a depressing force to the electronic element (refer to FIG. 1 together). In this step, the control module 60 can further control the depressing force generation apparatus 34 to apply the depressing force, so that the contact under the electronic element can more completely contact the probe in the test socket 50.

Step S500: The control module 60 tests the electronic element. In this step, the testing can be started when the contact under the electronic element has completely contacted the probe in the test socket 50. Based on this, the test is performed on the electronic element through the control module 60.

Based on the above, in some embodiments, the support frame 20 and the carrier platform 10 form a frame structure, the lifting module 31 is arranged on the top support 23 of the support frame 20, and the lifting module 31 fastens the lifting shaft rod 312 through the fastening module 33. Based on this configuration, when the lifting module 31 applies a depressing force to the electronic element through the depressing head 32, the entire frame structure presents an internal force balance, which may significantly reduce impact of the huge depressing force on another mechanism or assembly of the entire testing device. In the case of bearing a considerable depressing force, a deformation amount is also quite small.

In addition, in some embodiments, the fastening module 33 may directly lock or release the lifting shaft rod 312. Since the fastening module 33 and the depressing force generation apparatus 34 are coaxially configured, and the fastening module 33 is configured in the central part of the top support 23, the overall structure formed thereby has high strength, high reliability, and a long service life. The structure is also quite simple and occupies a small volume, especially in a height direction.

Furthermore, in some embodiments, the position and orientation of the test socket 50 are adjusted through the displacement adjustment module 40 to adapt to the depressing head 32, thereby providing convenience for calibration and fully ensuring integrity of the contact between the depressing head 32 and a to-be-tested electronic element.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An electronic element testing device with a fastening-based depressing mechanism, comprising:
a carrier platform;
a support frame, arranged on the carrier platform;
a depressing mechanism, connected to the support frame, wherein the depressing mechanism comprises:
a lifting module;
a depressing head, connected to the lifting module, wherein the lifting module is configured to drive the depressing head to move toward or away from the carrier platform; and
a fastening module, configured to fasten the lifting module;
a displacement adjustment module, arranged above the carrier platform; and
a test socket, comprising a slot for accommodating an electronic element, wherein the test socket is connected to the displacement adjustment module, and the displacement adjustment module is configured to adjust displacement of the test socket in at least one axial direction.

2. The electronic element testing device with a fastening-based depressing mechanism according to claim 1, wherein the fastening module is a clamping mechanism, the lifting module of the depressing mechanism comprises a lifting shaft rod, the depressing head is arranged on an end of the lifting shaft rod, the clamping mechanism is configured to constantly fasten the lifting shaft rod, and the clamping mechanism is controlled to release the lifting shaft rod.

3. The electronic element testing device with a fastening-based depressing mechanism according to claim 2, wherein the clamping mechanism comprises a clamping block, a spring, and a piston block, the spring is configured to constantly drive the clamping block to fasten the lifting shaft rod, and in response to the piston block being driven by an air pressure, the piston block is configured to drive the clamping block to move against an elastic force of the spring, so that the clamping block releases the lifting shaft rod.

4. The electronic element testing device with a fastening-based depressing mechanism according to claim 1, further comprising a control module electrically connected to the depressing mechanism, wherein the control module is configured to control the fastening module of the depressing mechanism to release a lifting shaft rod, and control the lifting module to drive the depressing head to contact the electronic element in the test socket, and the displacement adjustment module is configured to selectively adjust the displacement of the test socket in the at least one axial direction.

5. The electronic element testing device with a fastening-based depressing mechanism according to claim 1, wherein the displacement adjustment module comprises a first substrate and a second substrate, the first substrate is arranged on the carrier platform, the second substrate is arranged on the first substrate, the first substrate is configured to adjust a position of the test socket along an X-axis direction and a Y-axis direction, and the second substrate is configured to adjust the position of the test socket along a Z-axis direction.

6. The electronic element testing device with a fastening-based depressing mechanism according to claim 5, wherein the displacement adjustment module further comprises a plurality of adjustment members, and the plurality of adjustment members respectively pass through the first substrate and the second substrate, so that the first substrate is arranged on the carrier platform and the second substrate is arranged on the first substrate.

7. The electronic element testing device with a fastening-based depressing mechanism according to claim 6, wherein each of the adjustment members comprises:
an adjustment bolt, comprising an adjustment portion and a body portion;
a fixing bolt, comprising a head portion and a pass-through portion, wherein the fixing bolt passes through the adjustment bolt through the adjustment portion and is bonded to the first substrate or the second substrate;
an adjustment nut, sleeved on the body portion; and
a gasket, sleeved on the pass-through portion and located between the adjustment portion and the head portion.

8. The electronic element testing device with a fastening-based depressing mechanism according to claim 1, wherein the support frame comprises:
a first support, wherein one end of the first support is connected to one side of the carrier platform;
a second support, wherein one end of the second support is connected to an other side of the carrier platform to correspond to the first support; and
a top support, wherein two ends of the top support are respectively connected to an other end of the first support and an other end of the second support and are located between the first support and the second support; and
the depressing mechanism is arranged on the top support.

9. The electronic element testing device with a fastening-based depressing mechanism according to claim 1, wherein the depressing mechanism further comprises a depressing force generation apparatus, which is configured to apply a depressing force to the electronic element in the test socket.

10. A method for testing an electronic element by using a fastening-based depressing mechanism, comprising the following steps:
providing a control module, wherein the control module is configured to control a fastening module to release a lifting module, and control the lifting module to drive a depressing head to contact an electronic element in a test socket;
controlling, by the control module, the fastening module to fasten the lifting module;
attaching the electronic element in the test socket to the depressing head through a displacement adjustment module;
controlling, by the control module, a depressing force generation apparatus to apply a depressing force to the electronic element; and
testing, by the control module, the electronic element.
